(19) United States
(12) Patent Application Publication
(10) Pub. No.: US 2004/0026764 A1
(43) Pub. Date: Feb. 12, 2004

(54) Low-loss bipolar transistor and method of manufacturing the same

(76) Inventors: Fumihiko Hirose, Yokohama (JP); Koji Nakano, Yokohama (JP); Yutaka Souda, Toyonaka (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/212,222

(22) Filed: Aug. 6, 2002

(51) Int. Cl. H01L 27/082

(52) U.S. Cl. 257/591

(57) ABSTRACT

A low-loss bipolar transistor comprising a collector layer composed of an n⁺⁺ Si substrate and n⁻ Si film, a base layer composed of a p− SiGe film, an emitter layer composed of an n⁺ Si film, a base electrode, an emitter electrode, a collector electrode, and an insulating material to coat the exposed surface including the junction boundary of the base layer and collector layer, wherein when a total length of contact boundary per unit area in the area where the emitter electrode and base electrode are adjacently arranged is assumed to be X (mm/cm²) and the dopant density of the emitter layer is assumed to be Y (atom/cm³), the expressions X≧500 and Y≧9.0×10¹⁸−3.2×10¹⁵ X are satisfied.

### BACKGROUND OF THE INVENTION

1. Field of the Invention

The present invention relates to a low-loss bipolar transistor for use in a power supply circuit of power electronic apparatuses such as personal computers, mobile equipment and motor-driven inverters, and a method of manufacturing the same.

2. Description of the Related Art

A bipolar transistor, MOSFET (Metal Oxide Semiconductor Field Effect Transistor) or IGBT (Insulated Gate Bipolar Transistor) has been utilized as a switch element to turn on/off a current in a switching regulator circuit because of its simple structure, low manufacturing cost, low saturation voltage at the time of turning on, low loss caused by heating during switching operation, and other advantageous characteristics.

These power transistors are used in an emitter grounding circuit, for example, shown in FIG. 5. The circuit is just one example of a bipolar transistor, but the circuit configuration is almost the same as those using a MOSFET or IGBT. In this circuit, the emitter electrode 6 and collector electrode 8 of a transistor 10 are connected to a power supply 17 through a load 16.

To turn on a bipolar transistor 10 in this circuit, a base current is directed in the direction forward to a base and emitter assumed to be diodes. This lowers the impedance between the emitter and collector of a transistor 10, and a current flows in a load 16, and the transistor 10 turns on. Conversely, when no base current flows, the emitter-collector impedance becomes high, a current flowing into the load 16 is interrupted, and consequently the transistor 10 turns off.

Usually, to control the power applied to the load 16, a base current is turned on/off repeatedly and switched on/off within as short a time as possible. In this case the base current becomes a square wave, and the power transmitted to the load 16 from a power supply 17 can be varied by changing the on-off time ratio. This is called pulse-width modulation (PWM).

In PWM, an emitter-collector voltage of a transistor 10 is very close to zero during on operation, while the calorific power of the transistor 10 is kept low at off because the collector current is interrupted. That is, power is efficiently supplied from a power supply 17 to a load 16, suppressing loss at the transistor 10.

A transistor power loss in such a switch circuit is determined by the on-state voltage drop (Vₒₙ) and the switching time. The on-state voltage drop (Vₒₙ) mentioned here means a voltage drop occurring across the emitter and collector when the transistor is turned on. The product of the Vₒₙ multiplied by a current becomes to a power loss when a transistor is turned on, and the Vₒₙ is preferably as small as possible.

As for the switching time, while a transistor is switched, a current is held flowing in a transistor and the emitter-collector voltage transitionally rises, causing heating of a transistor. Namely, as the switching time becomes long, the power loss increases. A power loss energy is consumed as heating in a circuit, resulting in overheating of a transistor. To prevent such a phenomenon, it is necessary to attach a heat sink to a transistor to improve the radiating performance of a transistor. However, the attachment of a heat sink increases the size of a circuit and its manufacturing cost. Therefore, it is essential to decrease the power loss at ON time to minimize the on-state voltage drop and the switching time.

A conventional bipolar transistor for use as a switch element is not sufficiently low in its Vₒₙ and not sufficiently short in the switching time. For instance, even a bipolar transistor capable of handling 10 A or greater as main current provides a minimum of 0.5 V with a rated current; the rated current is considered to be a main current value when a current density of a chip is 80 A per cm². It is to be noted that most bipolar transistors need one microsecond (μs) as a switching time.

Most MOSFETs provide the Vₒₙ greater than 1.0 V with a rated current, and need several hundred nanoseconds (ns) as a switching time.

Further, in IGBT, the Vₒₙ is 1.2 V or greater with a rated current, and the switching time is 1-10 μs or higher.

Accordingly, to decrease a power loss in a conventional power transistor, it is required to lower the Vₒₙ below 1.0 V with a rated current value and shorten the switching time under 100 ns.

Usually, the voltage of a power supply 17 is set to 10 V or greater. When a transistor 10 is turned off, the power supply voltage is applied across an emitter electrode 6 and a collector electrode 8, but a voltage drop across a base electrode 7 and emitter electrode 6 is about 1 V. Thus, most of the supply voltage is applied to the base and collector. Therefore, the setting of supply voltage is limited by a breakdown voltage when a transistor is reverse-biased across its base and collector. It is thus desired to set the breakdown voltage as high as possible.

The breakdown voltage of a transistor is much dependent on an air insulation breakdown voltage in a pn-junction exposure portion of a transistor. It can be said that this air insulation breakdown voltage of a pn-junction exposure portion decides the breakdown voltage of a transistor. Therefore, improving the insulation of a pn-junction exposure portion means to improve the transistor breakdown voltage.

As a conventional method of improving the transistor breakdown voltage, a thermal oxidation process has been known. The surface of a transistor (including a pn-junction exposure portion) is oxidized in the atmosphere of oxygen or vapor below 800° C. to form an oxide film (an insulating film) covering a transistor. However, a thermal oxidation process needs an exclusive oxidizing apparatus which is expensive. Further, the formed film thickness is under 0.05 μm (50 nm), which is not enough to ensure sufficient insulation from air. Moreover, the apparatus is prone to be affected by contamination with impurities, and production of a stable quality element requires high quality control costs.

Another known method of improving a transistor breakdown voltage is coating an insulating film. A transistor is coated with a glass or polyamide resin so as to be covered by a film of these materials. However, this method has a problem that a leakage current is generated by movable ions contained in the coating film. In addition, the coefficient of thermal expansion of the insulating film is different from those of the materials constituting a transistor (Si and SiGe), and the elasticity of the film itself is poor and causes thermal distortion when the film is heated in a thermal processing step, and this will cause a malfunction of a transistor.

### BRIEF SUMMARY OF THE INVENTION

An object of the present invention is to provide a low-loss bipolar transistor with a low on-state voltage drop, short switching time and high reliability which prevents a leakage current caused by movable ions and deterioration of electrical characteristics resulting from thermal distortion, and a method of manufacturing the same.

Breakdown voltage of an SiGe transistor is determined by an air insulating breakdown voltage in a pn-junction exposure portion. Therefore, it is necessary to increase the air insulating breakdown voltage by coating the pn-junction exposure portion with insulation material to prevent direct contact with air.

We studied a conventional thermal oxidation process and insulating film coating method and obtained the following knowledge. These conventional methods are effective to some extent to improve the breakdown voltage of an Si transistor, but almost ineffective for an SiGe transistor. Because an SiGe transistor contains a junction of different materials of Si and SiGe whose coefficients of thermal expansion are different, causing a distortion inside an SiGe transistor. An oxide film formed by conventional thermal oxidation has poor elasticity, and when it is heated, thermal distortion occurred in a transistor induces distortion or dislocation on the surface of a coating film, and this is considered to be the cause of malfunction of a transistor.

If a pn-junction exposure portion is coated with water glass or polyamide resin, the coefficients of thermal expansion of these coating materials are largely different, and the coating may be cracked with time. Such a crack in the coating exposes a pn-junction exposure portion to air, and lower its air insulating breakdown voltage, and consequently decreases the breakdown voltage of a transistor itself.

If silicone is used instead for the coating of a pn-junction exposure portion, a crack will not occur in the coating material because there is almost no or small difference thermal expansion between the coating material and a transistor. Moreover, silicone will be still flexible without losing elasticity even after being degassed and hardened, and cause no cracks in the coating material even if suffering a physical shock. Thus, the breakdown voltage a transistor will not decrease for a long time, making a transistor highly reliable.

We proposed in Jpn. Pat. Appln. KOKAI Publication No. 2001-110816 a bipolar transistor adopting SiGe in a base layer. The patent disclosed a transistor having a 0.4 μm thick base layer of p-type SiGe containing Ge of 5 atom %, a 0.6 μm thick emitter layer of n-type Si and a 20 μm thick collector layer is of n-type Si (hereinafter referred to as the filed transistor). In the filed transistor, the base layer dopant density was 2×10¹⁷ atom/cm³, the collector layer dopant density was 5×10¹⁴ atom/cm³ and the emitter layer dopant density was 5×10¹⁸ atom/cm³. As a result, the breakdown voltage of the filed transistor was 150-225 V, and the switching time was under 100 ns, which surpassed any of conventional elements.

However, the Vₒₙ of the filed transistor is as relatively high as 10 V or greater with a rated current. It is thus necessary to lower the Vₒₙ to decrease a switching loss. Therefore, we have studied for decreasing the Vₒₙ and shortening the switching time, and improving the filed transistor, and achieved the present invention.

A low-loss bipolar transistor comprising: a first-conductive type semiconductor substrate; a collector layer composed of a first-conductive type Si film formed on the substrate; a base layer composed of a second-conductive type SiGe film formed on the collector layer; an emitter layer formed of a first-conductive type Si film formed on the base layer; a base electrode formed by removing a part of the emitter layer or reversing partially the conductive type of the emitter layer and providing a metal terminal to the removed or reversed portion; an emitter electrode formed by providing a metal terminal to the emitter layer; a collector electrode formed by providing a metal terminal to at least one of the substrate and the collector layer; and an insulating material to coat the exposed surface including a junction boundary between the base layer and the collector layer; wherein when a total length of contact boundary per unit area in the area where the emitter electrode and base electrode are adjacently arranged is assumed to be X (mm/cm²) and a dopant density of the emitter layer to be Y (atom/cm³), the expressions X≧500 and Y≧9.0×10¹⁸−3.2×10¹⁵X are satisfied.

The semiconductor substrate of the present invention is preferably a Si substrate having an epitaxially grown n⁺⁺ type thin film. The substrate used for the present invention is not limited to silicon, and a germanium substrate may be used.

The collector layer must have the same conduction type as that of a substrate, and is preferably an n⁻ type Si film. The base layer must have a different conduction type from that of a substrate, and should be a p-type SiGe film. The emitter layer must have the same conduction type as that of a substrate, and be an n-type Si film.

Emitter electrodes and a base electrode are preferably arranged like a comb in a plane view of field, or said emitter electrodes and said base electrodes are preferably arranged in a staggered fashion in such that each of the emitter electrodes is inserted into spaces defined between the base electrode and the base electrode, and such that each of the base electrodes is inserted into spaces defined between the emitter electrode and the emitter electrode. With such a planar arrangement, the total contact boundary length X per unit area of an electrode is increased, and the characteristics of a transistor are improved. Vₒₙ becomes 1.0 V or smaller, and switching time becomes 100 ns or shorter.

A method of manufacturing a low-loss bipolar transistor comprising the steps of:

(a) forming a collector layer composed of a first-conduction type Si film on a first-conductive type semiconductor substrate;

(b) forming a base layer composed of a second-conductive type SiGe film on the collector layer;

(c) forming an emitter layer composed of a first-conductive type Si film on the base layer;

(d) forming a base electrode by removing a part of the emitter layer or reversing partially the conductive type of the emitter layer and fitting a metal terminal into the removed or reversed portion;

(e) forming an emitter electrode by fitting a metal terminal on the emitter layer, wherein when a total length of a contact boundary per unit in the area where the emitter electrode and base electrode are adjacently arranged is assumed to be X (mm/cm²) and the dopant density of the emitter layer to be Y (atom/cm³), the emitter electrode and base electrode satisfy the expressions X≧500 and Y≧9.0×10¹⁸−3.2×10¹⁵X;

(f) forming a collector electrode by providing a metal terminal to at least one of the substrate and the collector layer;

(g) coating insulation material on the exposed surface including a junction boundary of the base layer and the collector layer, wherein the insulation material is gel or rubber state; and

(h) degassing and hardening the coated insulation material in a vacuum.

FIG. 7 is a graphical representation of the result of our study on the influence of the total length X of contact boundary and emitter dopant density upon the on-state voltage drop, in which the total length x (mm/cm²) of contact boundary is plotted along the abscissa while the emitter dopant density (atom/cm³) is plotted along the ordinate. It becomes apparent according to this graph that the on-state voltage drop decreases to 1.0 V or lower in the area where the region right-hand from the characteristic curve A (the region satisfying the above expression (1)) and the region upward from the characteristic curve B (the region satisfying the above expression (2)) are overlapped.

In a transistor of the present invention, the widths of an emitter electrode and a base electrode are narrowed, and the total length of the contact boundary between the emitter electrode and the base electrode is increased, i.e., the total length X of contact boundary per unit area is increased, whereby the area to conduct a collector current per unit area can be increased. This arrangement substantially or completely eliminates an area difficult to conduct a collector current which tends to occur around the centers of the widths of the emitter electrode and base electrode. And, the collector current flowing area per unit area increases and the on-state voltage drop decreases to 1.0 V or lower. Further, by the incorporation of Ge, the switching time is reduced to under 100 ns, and a switching loss is considerably decreased.

Moreover, the emitter layer dopant density is increased, and this provides the effect of dispersing a collector current which tends to concentrate on the area where the emitter electrode and base electrode are adjacently arranged (area 20 in FIG. 6). Dispersion of the collector current accelerates the flow of collector current up to the central area of the emitter electrode width, increases the area to conduct the current, and consequently decreases the on-state voltage drop.

The base layer preferably contains germanium above 2.5 atom % and below 15 atom %. As shown in FIG. 8, the switching time becomes slow 400-500 ns if the Ge content of a base layer is below 2.5 atom %, while it becomes faster than 100 ns if the Ge content is above 2.5 atom %. Particularly, when the Ge content is above 4 atom %, the switching time becomes stable at under 100 ns. However, if the Ge content of the base layer exceeds 15 atom %, a leakage current is generated across the collector and base, the function as a transistor is spoiled, and the amplifying function is lost. Therefore, we have set the upper limit value of Ge content to 15 atom %.

For increasing the on-state voltage drop, it is essential to increase the contact boundary length X by increasing the emitter dopant density.

Now, the reason why SiGe is used for a base layer will be explained. Since a base layer is composed of SiGe, distortion occurs in the base layer and collector layer, and the lifetime of minority of carriers in the base layer is reduced. This decreases the electric charge stored in the base layer, and results in reduction of the switching time.

Chemical vapor phase deposition is used to increase the dopant density of impurity elements in an emitter layer. That is, a heated substrate is placed into a vacuum vessel filled with semiconductor material gas, and semiconductor thin films are piled up on the surface of the substrate (e.g., CVD technique). To pile up an n-type impurity doped Si film on the surface of a substrate, for instance, use a gas mixture of disilane (Si₂H₆), silane (SiH₄) and phosphine (PH₃) as a process gas. To pile up a P-type impurity doped SiGe film on the substrate surface, use a gas mixture of disilane (Si₂H₆), silane (SiH₄), diborane (B₂H₆) and germane (GeH₄) as a process gas. In this time, the substrate temperature is set to 650° C. or higher, for example. The n-type Si film P-dopant density is determined by the mixing ratio of disilane (Si₂H₆) or silane (SiH₄) to phosphine (PH₃). To obtain the P-dopant density over 1×10¹⁹/cm³, set the mixing ratio (PH₃ partial pressure/Si₂H₆ partial pressure or SiH₄ partial pressure) to 100 ppm or higher. When forming an n-type Si film corresponding to an emitter layer, diffusion and ion implantation techniques can be used in addition to the above-mentioned chemical vapor phase deposition.

The emitter electrodes 6 and the base electrodes 7 may be arranged like a comb teeth on the same plane, as shown in FIG. 1 and FIG. 2. In this case, it is desirable to make the comb teeth portions as narrow as possible and to make many comb teeth.

It is also permitted, as shown in FIG. 11, the emitter electrode 6 and base electrodes 7 have substantially equal width area.

The emitter electrodes and said base electrodes are arranged in a staggered fashion in such that each of the emitter electrodes is inserted into spaces defined between the base electrode and the base electrode, and such that each of the base electrodes is inserted into spaces defined between the emitter electrode and the emitter electrode in a plane view of field.

As another arrangement form to increase the total length X of boundary, spiral emitter electrodes 6 and base electrodes 7 are arranged coplanar on a circular substrate 2B.

Next, the effect to extend the total length X of boundary will be explained by reference to FIG. 6.

A collector current flowing across an emitter and collector at turning on a transistor tends to concentrate on an area where an emitter electrode 6 and a base electrode 7 are adjacently arranged, and area 20 where a collector current of high density flow appears, as shown in the drawing. This makes an area difficult to conduct a current around the central portions of the emitter electrode 6 and base electrode 7. If the widths of emitter electrode 6 and base electrode 7 are narrowed and the total length X of contact interface is increased, the area to conduct collector current per unit area can be increased. In other words, the extension of the total length X of boundary per unit area contributes to lower the transistor on-state voltage drop.

On the other hand, increasing the dopant density of emitter layer 5 has the effect of dispersing the collector current which tends to concentrate on the area 20 where the emitter electrode and base electrode are adjacently arranged. The dispersion of collector current makes the flow of collector current easy to up to the central portion of the emitter electrode 6 and increases the current flow area, and consequently lowers the on-state voltage drop of a transistor.

In a degassing step, the insulating coating material is degassed while being heated at a room temperature or predetermined temperature and depressurized at a predetermined pressure. The degassing temperature is preferably in a range of 23-100° C. The coating material is not sufficiently hardened below a room temperature, and the silicone is degraded above 100° C. The degassing pressure is preferably in a range of 0-500 Torr. Degassing pressure is above 500 Torr, and a time is required for ventilation until above 500 Torr.

Apply the insulating coating material under a room temperature and atmospheric pressure, and seal the whole transistor with the insulating coating material. The insulating coating material is desirably a gel or rubber state silicone. The silicone mentioned here means a polymer in which silicone (Si) and oxygen (O) are alternately coupled (siloxane coupling).

The average thickness of the insulating coating material is preferably over 2 mm and under 20 mm. Insulation of the pn-junction exposure portion from air is insufficient under 2 mm, and the gel state coating material may flow out of the casing before a degassing process over 20 mm.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of the invention.

FIG. 1 is a plane view showing a low-loss bipolar transistor according to the present invention;

FIG. 2 is a cross-sectional view of a transistor taken along a line II-II of FIG. 1;

FIG. 3 is a flowchart showing the steps of manufacturing a low-loss bipolar transistor of the invention;

FIGS. 4A-4K are views illustrating the steps of manufacturing a low-loss bipolar transistor of the invention;

FIG. 5 is a circuit diagram showing an example of an emitter grounding circuit to drive a transistor of the invention as a switch element;

FIG. 6 is a cross-sectional view visually showing the areas to conduct a collector current of high density for explanation of the effect of a transistor of the invention;

FIG. 7 is a graphical representation showing the relationship between the emitter dopant density and the contact length X for the on-state voltage drop of a transistor according to a first embodiment of the present invention;

FIG. 8 is graphical representation showing the dependence of the switching time upon the Ge density in respect to a transistor according to a second embodiment of the invention;

FIG. 9 is a graphical representation showing a breakdown voltage of a transistor (an example for comparing) before coating of silicone gel;

FIG. 10 is a graphical representation showing a breakdown voltage of a transistor (an embodiment) after coating of silicone gel;

FIG. 11 is a plane view showing a low-loss bipolar transistor according to another embodiment of the present invention; and

FIG. 12 is a plane view showing a low-loss bipolar transistor according to still another embodiment of the present invention.

### DETAILED DESCRIPTION OF THE INVENTION

Hereinafter the preferred embodiments of the present invention will be explained with reference to the accompanying drawings.

(Embodiment 1)

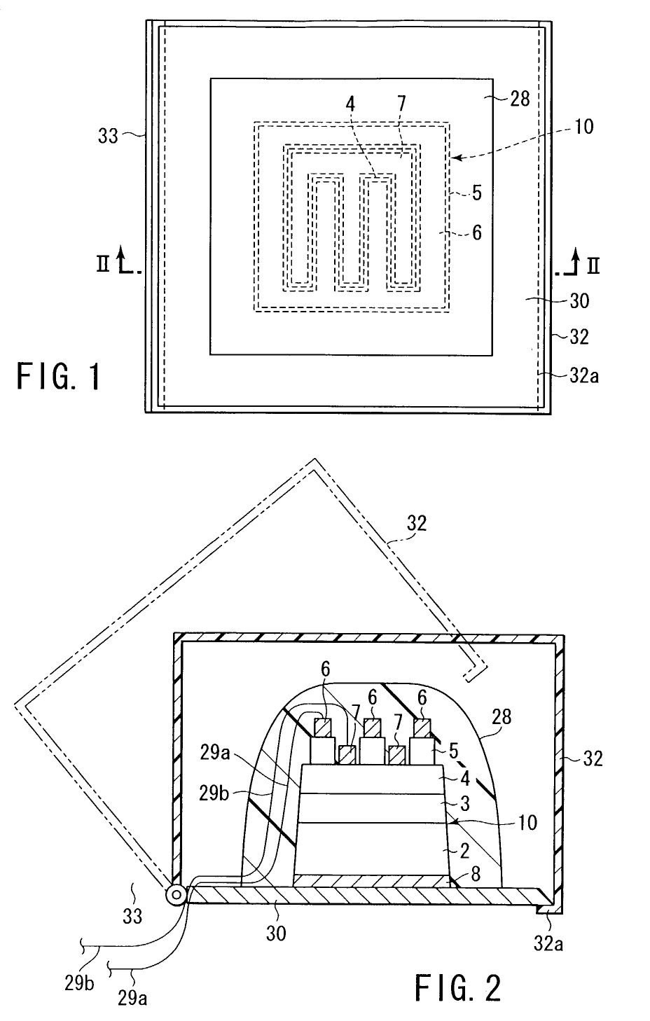

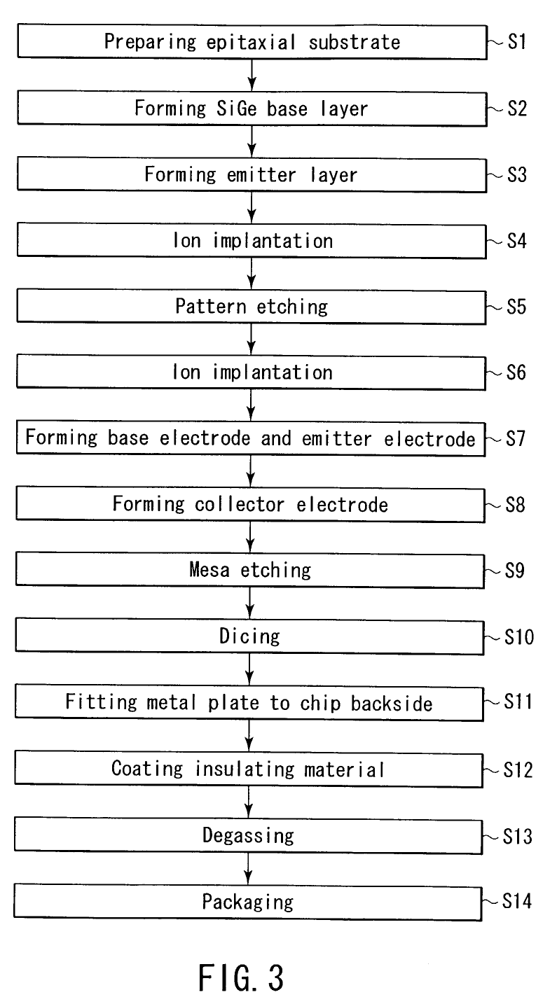

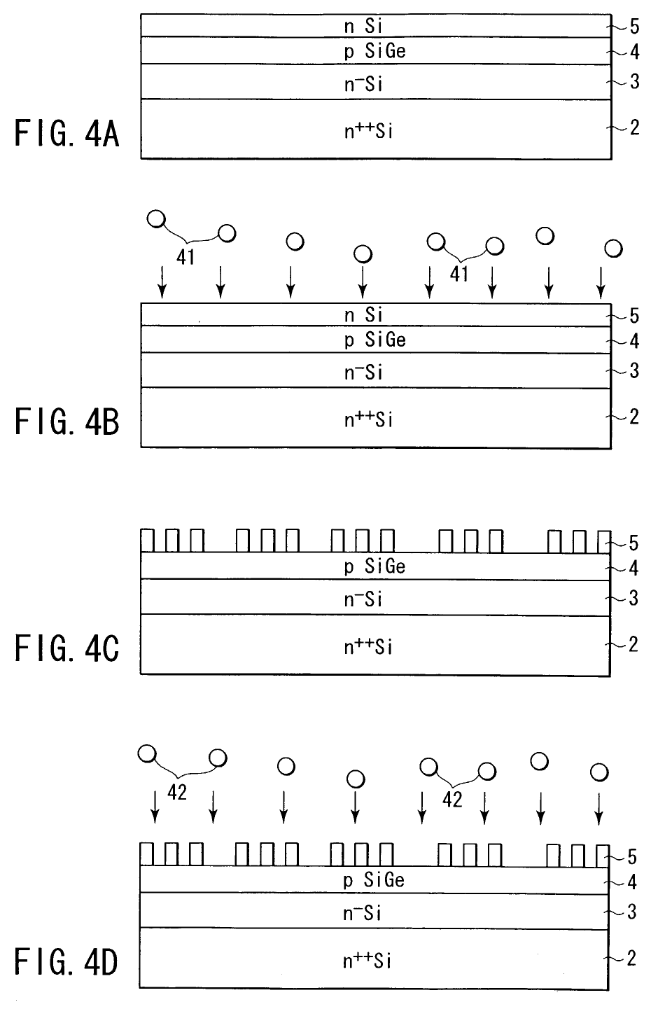

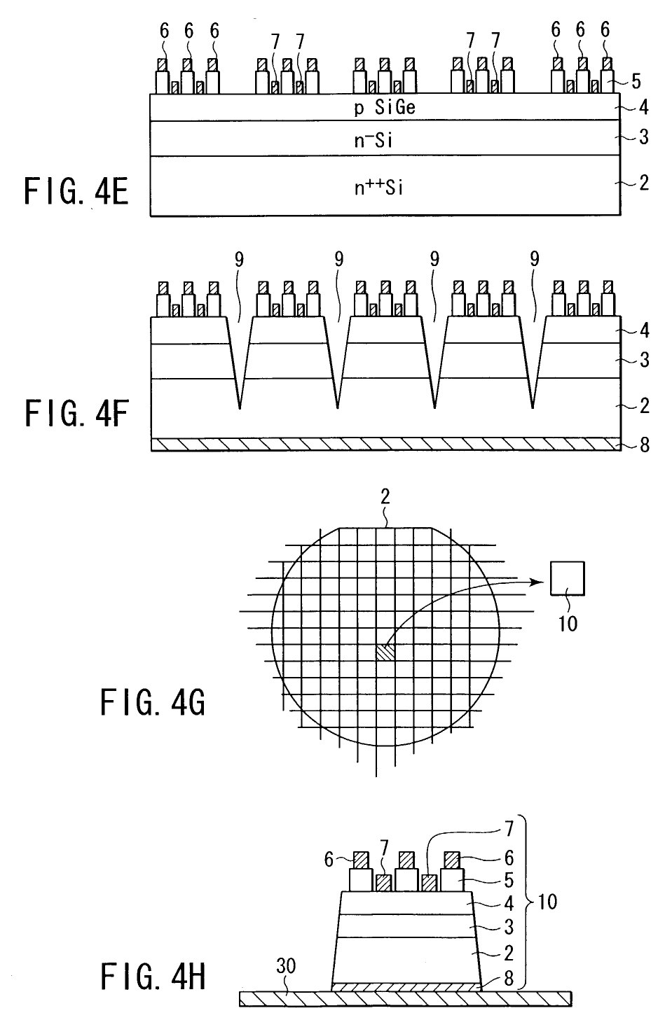

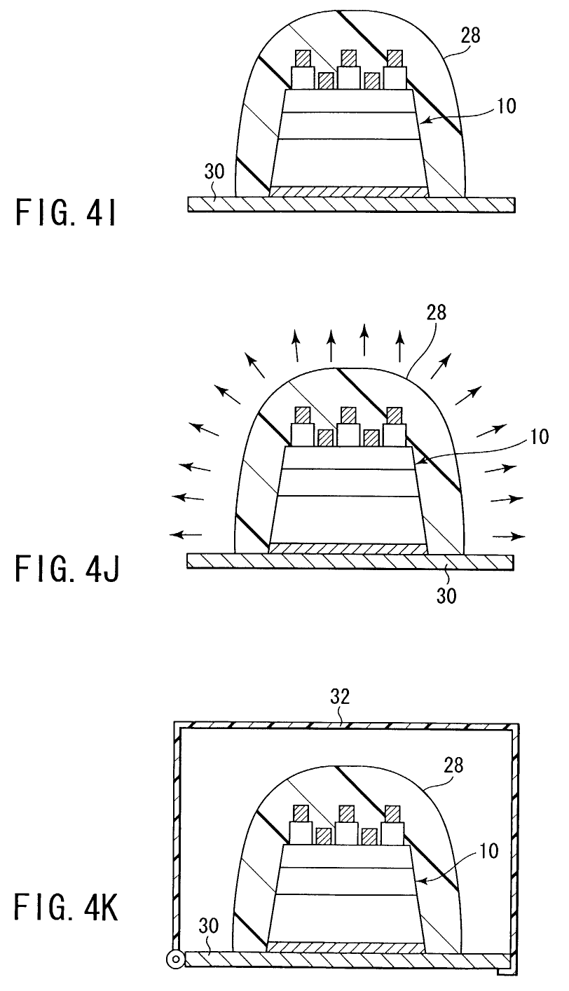

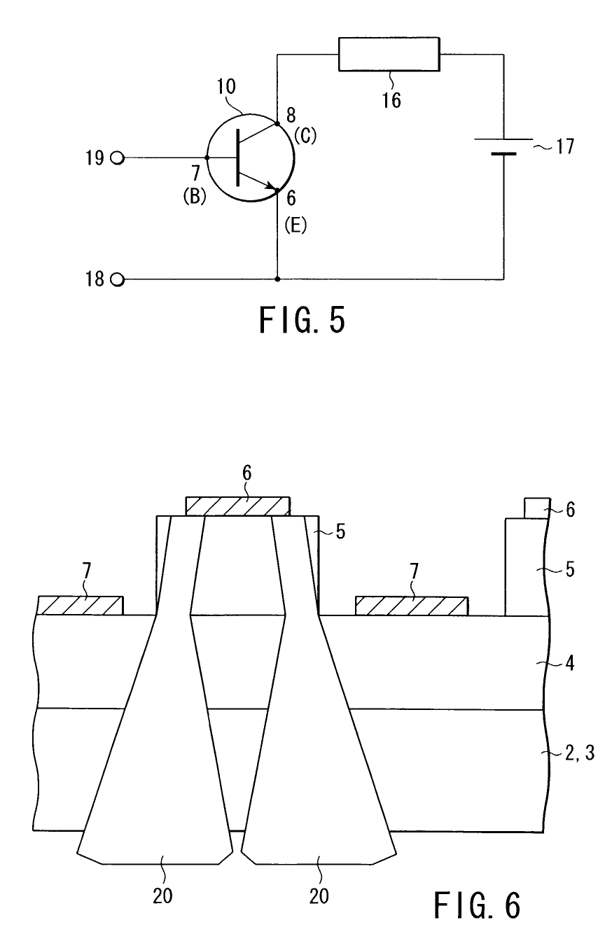

We manufactured a bipolar transistor 10 for a large electric power shown in FIGS. 1 and 2, as a first embodiment. A method of manufacturing a transistor 10 of the first embodiment will be explained by referring to FIG. 3 and FIGS. 4A-4K.

Prepare an Si substrate 2 with an epitaxially grown n⁺⁺ type silicon thin film piled up on the surface (step S1). The substrate 2 is a silicon wafer of 6 inches in diameter with the surface resistance of 0.001Ω·cm. Si layer 3, SiGe layer 4 and Si layer 5 are sequentially piled up on the substrate 2 using a chemical vapor deposition technique, and a multilayer body shown in FIG. 4A is obtained (steps S2, S3). The Si layer 3 is a phosphorus (P) doped 20 μm thick film with n⁻ type conduction, and functions as a collector layer. The Si layer 3 is deposited on the substrate 2 by using a gas mixture of disilane (Si₂H₆), silane (SiH₄) and phosphine (PH₃) as a process gas.

The SiGe layer 4 is a boron (B) doped 0.4 μm thick film with p-type conduction, and functions as a base layer. The SiGe layer 4 is deposited on the substrate 2 by using a gas mixture of disilane (Si₂H₆) or silane (SiH₄), diborane (B₂H₆) and germane (GeH₄) as a process gas. At this time, the substrate temperature is set to 650° C. or higher, for example, and the Ge content of the p-type SiGe layer is set to about 5 atom %. The base layer 4 is composed primarily of SiGe containing a predetermined or preferably 13% or lower amount of Ge. The thickness of the base layer 4 is preferably 0.15-0.93 μm.

The Si layer 5 is a 0.6 μm thick film with n-type conduction formed by doping ions (P) 41 based on ion implantation shown in FIG. 4B (step S4). This Si layer 5 functions as an emitter layer. The dopant density of the Si layer 5 is determined by the mixing ratio of phosphine (pH₃) to disilane (Si₂H₆) and silane (SiH₄). The P-dopant density of 1×10¹⁹/cm³ or greater can be obtained by setting the mixing ratio (PH₃ partial pressure/Si₂H₆ partial pressure or SiH₄ partial pressure) to 100 ppm or higher.

Pattern etching is carried over the Si layer 5 based on the RIE etching technique to expose a part of the surface of the base layer 4, as shown in FIG. 4C (step S5). Then, as shown in FIG. 4D, boron (B) ion 42 is doped on the exposed surface of the base layer 4 by ion implantation (step S6).

In this embodiment, the impurity doping volumes of layers 3, 4, 5 are each 5×10¹⁴ atom/cm³, 5×10¹⁷ atom/cm³, 5×10¹⁸ atom/cm³−1×10¹⁹ atom/cm³.

A base electrode 7 is formed on the base layer 4 and an emitter electrode is formed on the emitter layer 5 by evaporation, as shown in FIG. 4E (step S8).

Deep V-shape grooves 9 are formed in each of the element dissociation areas of a multilayer body by mesa etching, as shown in FIG. 4F (step S9). These deep V-shape grooves 9 reach to the half of the thickness of the substrate 2. The mesa etching uses a mixture of fluoric acid, nitric acid and acetic acid.

A chip 10 is cut out from a wafer 2 along the deep V-shape groove 9 with a dicing machine, as shown in FIG. 4G (step S10). The transistor chip 10 is 5×5 mm square in this embodiment.

A metal plate 30 is bonded to the back side of the chip 10 by soldering or gluing, as shown in FIG. 4H (step S11). The metal plate 30 is composed of copper, aluminum, iron or the like, and is made to have a predetermined thickness of 0.5-2.0 mm. The metal plate 30 contacts and conducts with a collector electrode 8, and functions as a collector electrode.

The transistor chip 10 is coated with gel state silicone 28 as insulation material at room temperature and atmospheric pressure, as shown in FIG. 4I (step S12). The gel state silicone 28 adopts KE1250 made by SHINETSU KAGAKUKOGYO CO., LTD. (JAPAN). Immediately after this coating process, the whole unit is put into a vacuum vessel, the vacuum vessel is degassed and left for 30 minutes, thereby eliminating bubbles remaining in the coated silicone 28 (step S13).

Next, the transistor chip 10 with the insulating coating material 28 and metal plate 30 is packaged by a plastic cover 32, as shown in FIG. 4K (step S14).

The cover 32 is coupled to the metal plate 30 through a hinge 33, as shown in FIG. 2. A cover end 32a is bent to be engaged with the edge of the metal plate 30. When the cover end 32a engaged with the edge of the metal plate 30, the cover 32 is closed and the transistor chip 10 coated with the insulation material 29 is completely covered by the cover 32. A numeral 29a indicates a lead wire connected to an emitter electrode 6. A numeral 29b indicates a lead wire connected to a base electrode 7.

Through the above described steps, a transistor 10 of the embodiment 1 shown in FIGS. 1 and 2 is obtained. The transistor 10 of this embodiment 1 is 5×5 mm square size, and its electrode pattern is like a comb as shown in FIG. 1. By adjusting the width of emitter electrode 6 and the comb width of base electrode 7 and by changing the number of comb teeth, we have manufactured the transistor by varying the peripheral length of adjacent electrodes 6, 7 in a range of 40-560 mm. The peripheral length of this range is equivalent to 160-2240 mm/cm² in the total length X of contact boundary per unit area.

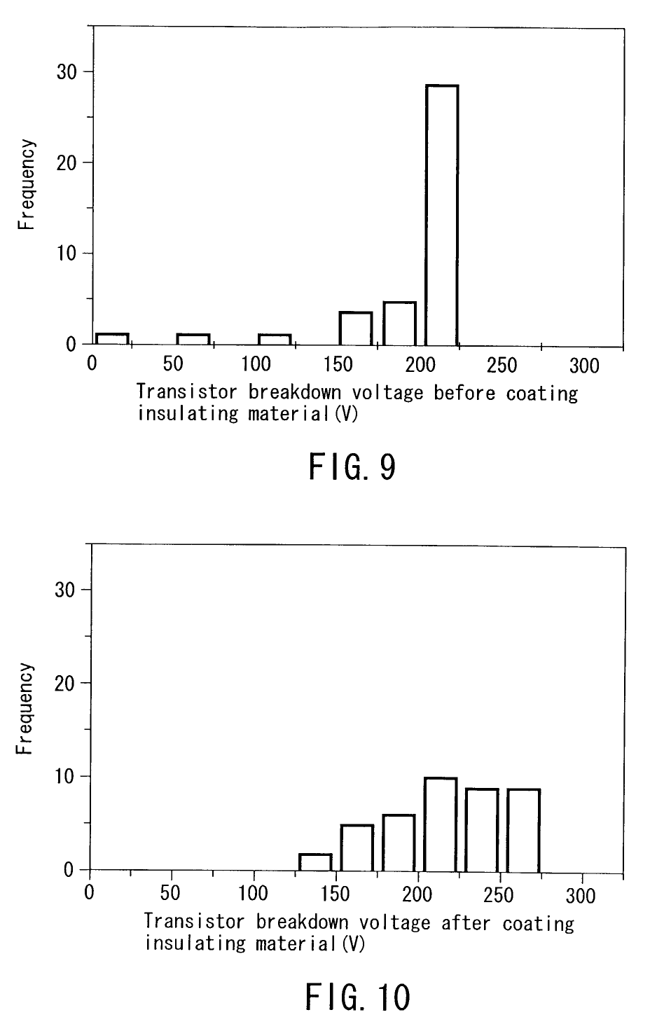

We have manufactured 42 samples for the embodiment 1, and examined the breakdown voltage distribution before and after coating silicone for each sample. The breakdown voltage distribution before the silicone coating is shown in FIG. 9, and that after the silicone coating is shown in FIG. 10. As seen from FIG. 9, the breakdown voltage before the silicone coating distributes mainly in a range of 200 V to a maximum of 225 V. After the silicone coating, as shown in FIG. 10, high breakdown voltages greater than 225 V appear and low voltages below 100 V disappear.

It is also to be noted that although the mean breakdown voltage of the bipolar transistor before the gel silicone coating is 193.1 V, it is increased up to 210.0 V after the silicone coating.

According to the above-described results, it is confirmed that the bipolar transistor of the present invention has the remarkable effect of improving the breakdown voltage.

In addition, we carried out other experiment: we chose eight transistors of the embodiment 1, applied 150 V to the emitters and collectors of these transistors under 125° C. by interrupting the base current, and measured the change in leakage current. As a result, it could be confirmed that the leakage current did not exceed 10 times the initial value in all the transistors within 1000 hours, and the transistors have the excellent durability against thermal distortion.

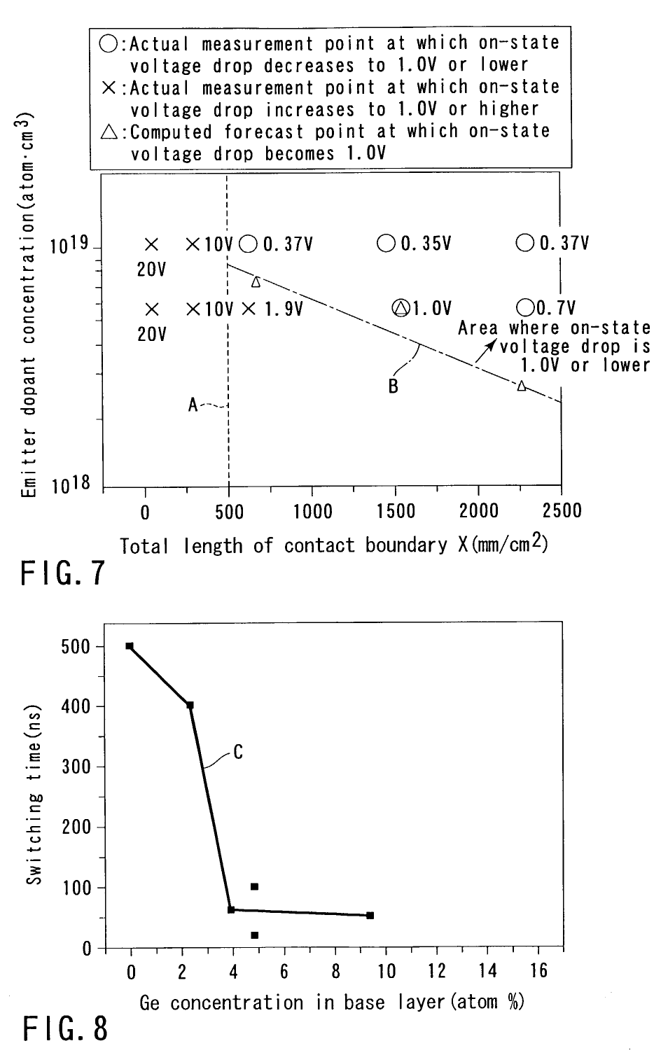

FIG. 7 shows the evaluations of on-state voltage drop of each transistor assuming a rated current to be 20 A. FIG. 7 graphically shows the influence of the total length X of contact boundary and the emitter dopant density upon the ON voltage by plotting the total length X (mm/cm²) of contact boundary along the abscissa while plotting the emitter dopant density (atom/cm³) along the ordinate. It is seen from this graph that assuming the contact length X to be X (mm/cm²) and the emitter layer dopant density to be Y (atom/cm³), the ON voltage becomes 1.0 V or lower when the expressions (1) X≧500 and (2) Y≧9.0×10¹⁸−3.2×10¹⁵ X are satisfied.

It is also to be noted that the silicone coating prevents adhesion of dust and impurities to the junction as well as preventing discharging. This will suppress deterioration of dielectric strength with time.

Silicone gel or silicone rubber in itself is inexpensive, and has a high insulation effect, and includes no movable ions, and even if it is coated on the exposed surface including the junction interface between the base and collector, a leakage current will not be generated in the coating, and a breakdown voltage will be increased by the effect of insulation from air.

In addition, the coating material composed of gel or rubber state silicone has excellent elasticity, and causes no thermal distortion in the portion contacting with the element itself, and consequently prevents deterioration of electrical characteristics due to distortion. Especially, in an SiGe transistor based on the contact structure of silicon germanium and silicon, distortion occurs in the element itself comprising a collector layer, a base layer and an emitter layer, and the probability of deterioration in the electrical characteristics of an element due to external distortion becomes high compared to a conventional Si transistor. Therefore, use of the coating by silicone gel or silicone rubber with no distortion between the elements will provide a stable quality SiGe transistor.

(Embodiment 2)

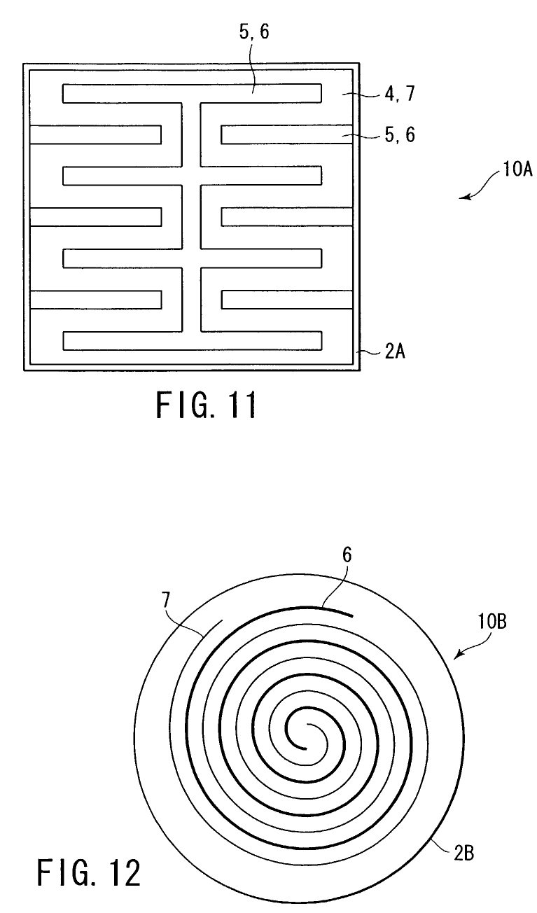

We manufactured a bipolar transistor 10A for a large electric power shown in FIG. 11 as a second embodiment. A method of manufacturing this transistor 10A of embodiment 2 will be explained hereinafter.

A 20 μm thick P-doped n-type Si layer 3, a 0.4 μm thick B-doped p-type SiGe layer 4 and a P-doped Si layer 5 are sequentially piled up on a n-type 0.001Ω·cm silicon substrate 2A by chemical vapor phase deposition. The doping concentrations of the three layers are each 5×10¹⁴ atom/cm³, 5×10¹⁷ atom/cm³ and 5×10¹⁸ atom/cm³. To pile up a p-type impurity doped SiGe film 4 on the Si layer 3, use a gas mixture of disilane (Si₂H₆), silane (SiH₄), diborane (B₂H₆) and germane (GeH₄) as a process gas. In this time, the substrate temperature is set to 650° C. or higher, for example. The Ge content in the SiGe layer 4 (base layer) is varied in an atom density range of 0-15% when the transistor 10A is manufactured.

In the transistor 10A of embodiment 2, an emitter electrode 6 and a base electrode 7 having substantially the same width are alternately arranged like a nest on the same plane. The widths of the electrodes 6 and 7 are the same 200 μm, for example.

To have an extended contact length X, a circular transistor 10B is also permitted, in which spiral emitter electrode 6 and base electrode 7 are arranged coplanar on a circular substrate 2B, as shown in FIG. 12.

FIG. 8 shows the relationship between the Ge concentration and the switching time in transistors having different Ge density base layers, by plotting the Ge concentration (atom %) in the base layer along the abscissa and the switching time (ns) along the ordinate. The boundary length X adopted is the one which satisfies the expressions described above. As seen from the characteristic curve C, the switching time is 500 ns when the base layer contains no Ge (Ge=0%), but it falls to 400 ns when the Ge concentration is 2.5-2.8 atom %, and below 100 ns when the Ge concentration is above 4 atom %. Further, we measured the switching time of the elements manufactured by the above-mentioned method, and could confirm that the switching time is suppressed to 100 ns or lower in any of ON and OFF time.

As a result, it becomes apparent that the switching time is about 500 ns when the Ge concentration in the base layer is below 2.5 atom %, while it falls to below 100 ns in the area where the Ge concentration is higher. It is also to be noted that a leakage current occurs across the emitter and base and across the collector and base when the Ge concentration in the base layer is 15 atom %, and the function as a transistor is lost. As for the on-state voltage drop, the dependence upon the Ge concentration was not recognized in the transistors which functioned.

(Comparison 1)

In this example, we formed an oxide film by dry oxidation on the surface of a transistor.

However, an exclusive apparatus is necessary, and there is a problem that movable ions are prone to mix into a film due to contamination of the apparatus.

Therefore, we manufactured about 100 transistors in one trial manufacture out of three, and obtained the result that all transistors with 10 V or lower breakdown voltage were defective. And, in the second and third trials, the breakdown voltage was increased in a few transistors, but the improvement probability was 20% or lower. Besides, the probability of increasing the voltage was also about 20%, and it was confirmed that the effect of increasing the breakdown voltage was very small compared to the embodiment 1.

It was also confirmed that the cause of the defect in the comparison 1 is the leakage current generated by the movable ions in the oxide film.

(Comparison 2)

In this example, we formed a glass coating film by applying a glass to the surface of a transistor.

However, since movable ions and a structure with a negative electric charge coexist in the glass, a leakage current was large as in the comparison 1, and the breakdown voltage decrease is not recognized compared to the case where the glass coating film was not formed.

As to thermal durability, we made the similar experiment as the embodiment 1, and obtained the result that most glass coating films were broken in 10-100 hours. This might result from the thermal distortion caused by movable ions in the glass coating film and the lack of elasticity of the film.

In a transistor according to the present invention, the widths of emitter electrode and base electrode are narrowed to increase the total length of the contact boundary between the emitter electrode and base electrode. In other words, by increasing the contact boundary length X per unit area, increase the area to conduct the collector current per unit area. This substantially or completely eliminates the area 20 difficult to conduct the collector current likely to occur around the centers of the emitter electrode and base electrode, and consequently increases the area to conduct the collector current per unit area and decrease the on-state voltage drop. In addition, the Ge doping reduces the switching time, and considerably decreases the switching loss.

Moreover, the emitter layer dopant density is increased to give a transistor the effect of dispersing a collector current which tends to concentrate on the area where the emitter electrode and base electrode are adjacently arranged. Dispersion of the collector current accelerates the flow of collector current up to the central area of the emitter electrode width, increases the area to conduct the current, and consequently decreases the on-state voltage drop. Further, the application of Ge reduces the switching time and decreases the switching loss.

Furthermore, in a transistor of the present invention, the exposed surface including a pn-junction interface is covered by an insulating coating material, and the breakdown voltage is increased, and deterioration of electrical characteristics caused by a leakage current generated by movable ions and thermal distortion can be prevented.

As explained above, according to the present invention, the on-state voltage drop is decreased to 1.0 V or lower, the switching time is reduced to 100 ns or less, and the switching loss is considerably decreased. These advantageous effects highly contribute to energy saving, lowed cost and compact design of power electronics circuits including an inverter for motor driving and a power supply for a personal computer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A low-loss bipolar transistor comprising:
a first-conductive type semiconductor substrate;
a collector layer composed of a first-conductive type Si film formed on said substrate;
a base layer composed of a second-conductive type SiGe film formed on said collector layer;
an emitter layer formed of a first-conductive type Si film formed on said base layer;
a base electrode formed by removing a part of said emitter layer or reversing partially the conductive type of said emitter layer and providing a metal terminal to the removed or reversed portion;
an emitter electrode formed by providing a metal terminal to said emitter layer;
a collector electrode formed by providing a metal terminal to at least one of said substrate and said collector layer; and
an insulating material to coat the exposed surface including a junction boundary between said base layer and said collector layer; wherein
when a total length of contact boundary per unit area in the area where said emitter electrode and base electrode are adjacently arranged is assumed to be X (mm/cm²) and a dopant density of said emitter layer to be Y (atom/cm³), the expressions X≧500 and Y≧9.0×10¹⁸−3.2×10¹⁵X are satisfied.

2. A transistor according to claim 1, wherein said insulating material comprises silicone gel or silicone rubber.

3. A transistor according to claim 1, wherein the average thickness of said insulating material is over 2 mm and under 20 mm.

4. A transistor according to claim 1, wherein said semiconductor substrate comprises an n⁺⁺ type Si substrate, said collector layer comprises an n⁻ type Si film, said base layer comprises a p type SiGe film, and said emitter layer comprises an n⁺ type Si layer.

5. A transistor according to claim 1, wherein said base layer contains germanium of 2.5-15 atom %.

6. A transistor according to claim 1, wherein said emitter electrodes and said base electrodes are arranged like a comb in a plane view of field, or said emitter electrodes and said base electrodes are arranged in a staggered fashion in such that each of the emitter electrodes is inserted into spaces defined between the base electrode and the base electrode, and such that each of the base electrodes is inserted into spaces defined between the emitter electrode and the emitter electrode.

7. A transistor according to claim 1, wherein an ON voltage is below 1.0 V and a switching time is shorter than 100 ns.

8. A method of manufacturing a low-loss bipolar transistor comprising the steps of:
(a) forming a collector layer composed of a first-conduction type Si film on a first-conductive type semiconductor substrate;
(b) forming a base layer composed of a second-conductive type SiGe film on said collector layer;
(c) forming an emitter layer composed of a first-conductive type Si film on said base layer;
(d) forming a base electrode by removing a part of said emitter layer or reversing partially the conductive type of said emitter layer and fitting a metal terminal into said removed or reversed portion;
(e) forming an emitter electrode by fitting a metal terminal on said emitter layer, wherein when a total length of a contact boundary per unit in the area where said emitter electrode and base electrode are adjacently arranged is assumed to be X (mm/cm²) and the dopant density of said emitter layer to be Y (atom/cm³), said emitter electrode and base electrode satisfy the expressions X≧500 and Y≧9.0×10¹⁸−3.2×10¹⁵ X;
(f) forming a collector electrode by providing a metal terminal to at least one of said substrate and said collector layer;
(g) coating insulation material on the exposed surface including a junction boundary of said base layer and said collector layer, wherein said insulation material is gel or rubber state; and
(h) degassing and hardening said coated insulation material in a vacuum.

9. A method according to claim 8, wherein said step (g) includes coating gel-state silicone on said exposed surface as said insulating material.

10. A method according to claim 8, wherein said step (h) includes degassing said insulating material at room temperature or a predetermined heating temperature and under a predetermined reducing pressure.
